(19) United States
(12) Patent Application Publication
(10) Pub. No.: US 2004/0252737 A1
(43) Pub. Date: Dec. 16, 2004

(54) Zinc oxide based nanorod with quantum well or coaxial quantum structure

(76) Inventors: Gyu Chul Yi, Pohang-city (KR); Won Il Park, Pohang-city (KR)

Correspondence Address: ROTHWELL, FIGG, ERNST & MANBECK, P.C., 1425 K STREET, N.W., SUITE 800, WASHINGTON, DC, 20005, US

(21) Appl. No.: 10/461,439

(22) Filed: Jun. 16, 2003

(51) Int. Cl. H01S 3/14; H01S 5/00; H01L 29/12

(52) U.S. Cl. 372/43; 372/39; 257/43

(57) ABSTRACT

A zinc oxide (ZnO) based nanorod is provided. The ZnO based nanorod has a quantum well or a coaxial quantum structure and is formed by alternately laminating two or more layers selected from the group consisting of a zinc oxide layer; and a layer of a material which has a lattice constant similar to that of zinc oxide, at one or more cycle.

### BACKGROUND OF THE INVENTION

1. Field of the Invention

The present invention relates to a zinc oxide based nanorod, and more particularly, to a zinc oxide based nanorod with a quantum well or a coaxial quantum structure, the quantum well or the coaxial quantum structure being formed by alternately laminating two or more layers selected from the group consisting of a zinc oxide layer and a layer of a material which has a lattice constant similar to that of zinc oxide, at one or more cycle.

2. Description of the Related Art

As well known in the art, zinc oxide (ZnO) is a kind of semiconductor material with a wide direct transition band structure of 3.3 eV at room temperature and can be used for an ultraviolet or blue light emitting device, like GaN. In particular, because ZnO has an exciton association energy more than twice greater than a thermal energy at room temperature, excitons are stable at room temperature, thereby allowing ZnO to have a low excitation strength. Therefore, ZnO can be used for high efficiency optical devices. When magnesium (Mg) or cadmium (Cd) with an ionic radius similar to that of Zn²⁺ is added to ZnO, a band gap ranging from 2.8 eV to 4 eV can be obtained. As such, devices for detecting or emitting light of a desired wavelength band can be manufactured by adjusting the molar ratio of Mg or Cd. Recently, the observation of lasing in ZnO nanorods at room temperature was reported. This report demonstrates that individual ZnO nanorods act as laser cavities and thus ZnO is very useful for nano-sized laser device applications.

Generally, in order to develop a laser device comprised of a single nanorod, a nanorod which has a complicated structure is required. However, a simple monostructural nanorod has been mainly manufactured until now. Although the manufacture of heterojunction nanorods was often reported, it is difficult to control a film thickness in an angstrom (A) unit because an interface of the heterojunction structure is not sharp.

### SUMMARY OF THE INVENTION

The present invention provides a zinc oxide based nanorod with a quantum well or a coaxial quantum structure having a thin thickness of several angstrom to several hundreds nanometer or more. The quantum well or the coaxial quantum structure is formed by alternately laminating two or more layers selected from the group consisting of a zinc oxide layer; and a layer of a material which has a lattice constant similar to that of zinc oxide, at one or more cycle.

According to an aspect of the present invention, there is provided a zinc oxide based nanorod with a quantum well or a coaxial quantum structure.

According to another aspect of the present invention, there is provided a nano-scale device using the nanorod of the present invention.

### BRIEF DESCRIPTION OF THE DRAWINGS

The above and other features and advantages of the present invention will become more apparent by describing in detail exemplary embodiments thereof with reference to the attached drawings in which:

FIG. 1 is a diagram of a zinc oxide (ZnO) based nanorod with a quantum well structure according to the present invention;

FIG. 2 is a transmission electron microscopy (TEM) of a ZnO based nanorod with a quantum well structure according to the present invention;

FIG. 3 is a comparative graph of low temperature photoluminescence (PL) spectra for ZnO/ZnMgO nanorod quantum structures of the present invention and conventional ZnO/ZnMgO nanorod heterostructurtes;

FIG. 4 is a diagram of a zinc oxide (ZnO) based nanorod with a coaxial quantum structure according to the present invention; and

FIGS. 5A and 5B are transmission electron microscopy (TEM) photographs of a ZnO based nanorods with a coaxial quantum structure according to the present invention.

FIG. 6 is a comparative graph of room temperature photoluminescence (PL) spectra for ZnO based nanorod with a coaxial quantum structure of the present invention and conventional ZnO nanorods.

### DETAILED DESCRIPTION OF THE INVENTION

Hereinafter, exemplary embodiments of zinc oxide (ZnO) based nanorods according to the present invention will be described in detail with reference to the accompanying drawings.

When illustrative descriptions about related arts or construction of the present invention are deemed to make the subject of the present invention unclear, detailed descriptions thereof will be omitted. In addition, because the terms to be described later are defined with respect to their functions in the present invention, they can vary according to a user, an intention of an operator, or a typical practice. Therefore, the definition of terms must be made on the basis of the full description of the present invention.

Schematic background of invention will first be described.

Generally, it is known that it is very difficult to manufacture actual devices using nanomaterials by artificial manipulation. However, because nanorods can have a relatively long size, their rearrangement by artificial manipulation is relatively easy. In particular, with respect to semiconductor nanorods, because it is possible to manufacture nanorods having p-type or n-type semiconductivity according to the type of impurities to be doped, semiconductor nanorods are very useful for device applications. However, most conventional nanorods cannot be used for the manufacture of devices due to their simple monostructures. For the purpose of the manufacture of devices, cross-junctions between such nanorods are required. In this case, however, there arises a problem such as lowered performance of devices due to a small junction area. In addition, the life span and stability of devices may be adversely influenced.

In order to overcome the aforementioned problems, the present invention provides a zinc oxide based nanorod with a quantum well or a coaxial quantum structure.

According to a preferred embodiment of the present invention, the quantum well or the coaxial quantum structure is formed by alternately laminating two or more layers selected from the group consisting of a zinc oxide layer; and a Zn₁₋ₓMₓO layer, where M is Mg, Cd, Mn, Fe, Cu, or Co, and x is 0<x<1, and an alloy thereof, at one or more cycle.

According to another preferred embodiment of the present invention, the quantum well or the coaxial quantum structure is formed by alternately laminating two or more layers selected from the group consisting of a zinc oxide layer; and a metal oxide layer of one or more selected from the group consisting of MgO, Al₂O₃, TiO₂ and an alloy thereof, at one or more cycle.

According to still another preferred embodiment of the present invention, the quantum well or the coaxial quantum structure is formed by alternately laminating two or more layers selected from the group consisting of a zinc oxide layer; and a semiconductor layer of one or more selected from the group consisting of GaN, AlN, InN, GaAs, InP, GaSb, SiC, ZnSe, CdS, ZnS and an alloy thereof, at one or more cycle.

The ZnO based nanorod of the present invention may be manufactured using general chemical vapor deposition and, in some cases, a physical method such as sputtering and pulse laser deposition as well as a conventional vapor-phase transport process using a catalyst of a metal, for example gold.

Preferably, the ZnO based nanorod of the present invention may be manufactured using metal-organic chemical vapor deposition (MOCVD) in the absence of a metal catalyst. Unlike a conventional nanorod manufacturing method using a metal catalyst, such metal catalyst-free method can control a film thickness in an angstrom unit and make distinct interfaces, so that atomic or molecular particles in the form of ultrafine films can be adsorbed selectively on the tips or stems of nanorods and then grow therefrom.

Also, the present invention provides a nano-scale device using the nanorod of the present invention.

A ZnO based nanorod of the present invention has a quantum well or a coaxial quantum structure, which is useful for high efficiency light emitting devices, due to its strong exciton binding energy. When a heterogeneous material such as magnesium (Mg), cadmium (Cd), and manganese (Mn) is added to ZnO, a band gap is changed. In this regard, in the case of alternately laminating a ZnMgO layer, a ZnCdO layer, and a ZnMnO layer, a quantum well or coaxial quantum structure is formed. Such quantum well or coaxial quantum structure can lead specific physical phenomena because electrons, holes, or electron-hole pairs, also called excitons, are confined within a thin layer. By using such physical phenomena, it is possible to manufacture electronic nano-scale devices with extraordinarily fast information processing speed as well as high efficiency light emitting nano-scale devices.

In addition, ZnO based nanorod of the present invention have excellent electrical properties and optical properties. Because the nanorods are orderly oriented in the direction of perpendicular to a substrate and are very uniform in terms of their size, density, and length, they can be used for manufacturing actually applicable nano-scale devices or arrays of such nano-scale devices.

Hereinafter, the present invention will be described more specifically by Examples and FIGs. However, the following Examples and FIGs are provided only for illustration and the present invention is not limited thereto.

### EXAMPLE 1

### ZnO Based Nanorod with a Quantum Well Structure

ZnO based nanorod with a quantum well structure having a thickness of several to several tens angstrom were prepared. The quantum well structure was comprised of 10 cycles of ZnO layers and ZnMgO layers. In detail, a Zn-containing organic metal, dimethylzinc [Zn(CH₃)₂], a Mg-containing organic metal, biscyclopentadienyl-Mg [(C₅H₅)₂Mg], and an oxygen (O₂) gas were used as reactants and argon as a carrier gas. By appropriately controlling the flow rates of the carrier argon gas and the oxygen gas via respective supply lines, nanorod with a highly complicated ZnO/ZnMgO quantum well structure could be manufactured.

Preferably, a reactor was maintained to have a pressure of 10⁻⁵ to 760 mmHg and a temperature of 400-700° C. After ZnO nanorod was grown for an hour, the dimethylzinc and biscyclopentadienyl-Mg, which had run into an exhaust line, were appropriately supplied to the reactor to thereby form ZnMgO/ZnO layers on the ZnO nanorod. The content of Mg in the ZnMgO layer was 20 at. % (atomic percent).

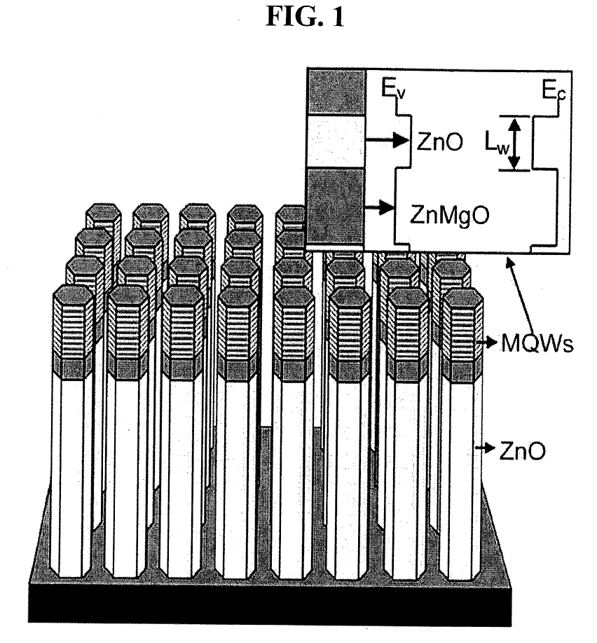

The nanorod thus prepared are shown in FIG. 1. According to the observation results of the nanorod using a scanning electron microscope, the diameter was in the range of 20 to 50 nm and the length was about 1 μm. The nanorods were orderly oriented in the direction of perpendicular to a substrate, and distributed in high density. In addition, the nanorods had uniform sizes. When needed, the length of nanorods can be extended up to several micrometers.

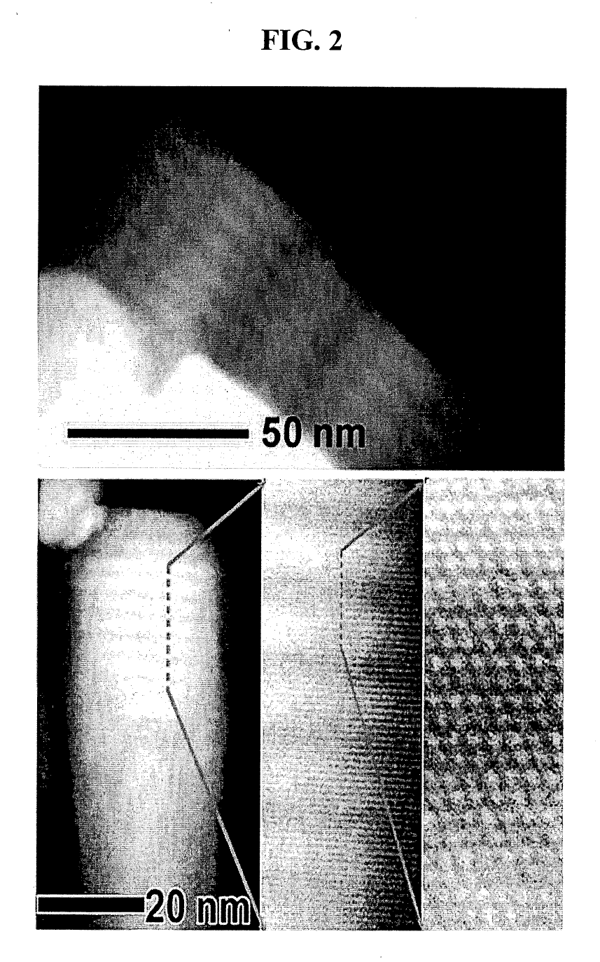

The quantum well structure of ZnMgO/ZnO layers and the thickness of each layer were determined using a transmission electron microscopy (TEM) and the results are shown in FIG. 2. Referring to FIG. 2, the quantum well structure had ZnMgO layers and ZnO layers, which were alternately laminated one onto another at 10 cycles. According to the investigation results using a high magnification scanning electron microscopy, the quantum well structure did not have defects such as dislocation and point defects and epitaxially grew on the ZnO nanorods. The content of Mg, which was measured using an energy dispersion type X-ray analyzer (EDAX), was 20 at. %. When needed, the content of Mg can be adjusted by appropriately controlling the flow rate of the reactants and the vapor pressure.

When ultrafine layered quantum well structures are formed, excitions are confined in the quantum wells due to the quantum effect. This fact can be demonstrated by investigating positions of peaks of PL spectrum. As the thickness of the quantum well decreases, the quantum confinement effect increases, thereby increasing the energies of emission peaks.

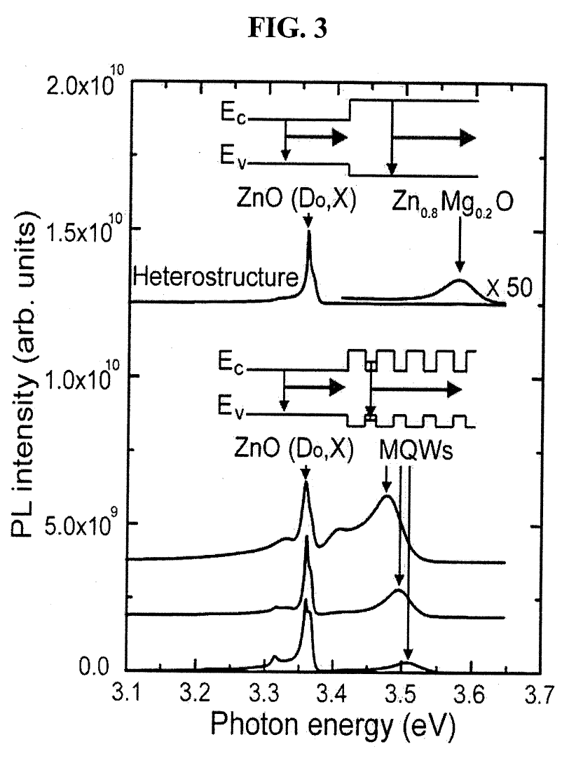

Referring to FIG. 3, similar phenomena were observed in nanorod quantum structures of the present invention. While exciton peaks were observed at 3.36 eV and 3.58 eV for ZnMgO/ZnO nanorods, new emission peaks were observed at 3.478 eV, 3.496 eV, and 3.515 eV for nanorods with a quantum well structure comprised of ultrafine ZnO/ZnMgO layers. In addition, the systematic increase in PL emission energy with reducing well width is consistent with the quantum confinement effect. Such new emission peaks demonstrate that excitons are strongly confined in ZnO wells. Therefore, it can be seen that ZnO/ZnMgO nanorod quantum structures of the present invention were successfully manufactured.

### EXAMPLE 2

### ZnO Based Nanorod with a Coaxial Quantum Structure

ZnO based nanorod with a coaxial quantum structure was also prepared. The coaxial quantum structures were comprised of core ZnO layers and shell layers composed of either GaN or ZnMgO. In detail, a Zn-containing organic metal, dimethylzinc [Zn(CH₃)₂], a Mg-containing organic metal, biscyclopentadienyl-Mg [(C₅H₅)₂Mg], and an oxygen (O₂) gas were used as reactants and argon gas as a carrier gas for ZnO or ZnMgO growth. For GaN growth, trimethylgalium [Ga(CH₃)₃] and ammonia (NH₃) gas were used as reactants.

First, for the growth of core ZnO naorods with extremely small diameter of about 10 nm, a reactor was maintained to a relatively high temperature of 800-1000° C., and ZnO nanorods were fabricated for 1 hr. As a result, grown ZnO nanorods exhibited the mean diameter and length of 10 nm and 2-5 μm, respectively.

Second, for the growth of ZnMgO or GaN shell layers, growth conditions were carefully controlled. For example, ZnMgO shell layers were grown by decreasing the growth temperature down to 400-500° C., since lateral growth on ZnO nanorod stems rather than ZnO tips is predominant at a relatively low temperature. For GaN shell layer growth, a reactor was maintained to have a pressure of 5 to 760 mmHg and a temperature of 500-1000° C. The growth times of core ZnO and shell layer (ZnMgO, GaN) were in the range of 1 hr and 1-30 min, respectively.

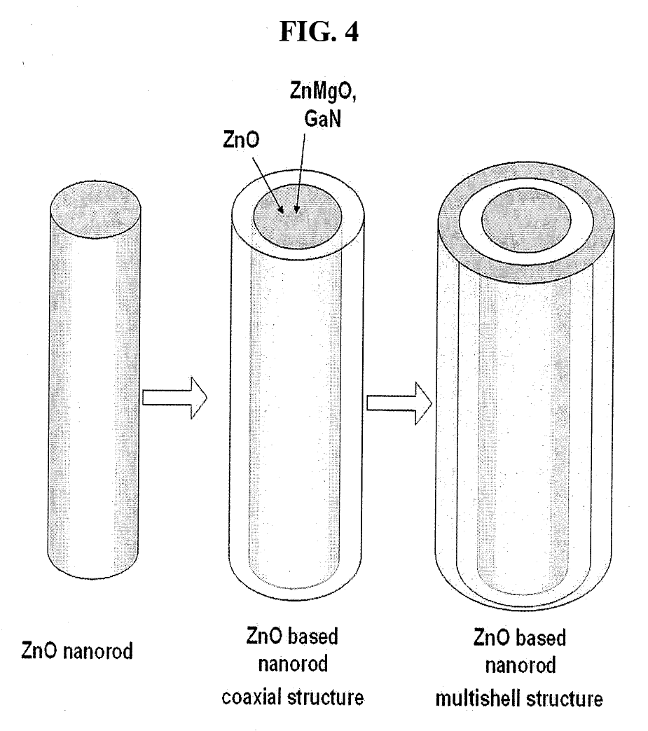

ZnO based nanorod coaxial quantum structures thus prepared are shown in FIG. 4. According to the observation results of the nanorods using a scanning electron microscope, the ZnMgO coated nanorods for 5 min and 10 min exhibited the significant increase in their diameter of 35 nm, and 45 nm, respectively, while the nanorod length change was ignorable. Those results strongly indicate that the dominant growth direction of ZnMgO layers was radial direction and ZnO/ZnMgO coaxial quantum structures were synthesized successfully. Similar results were also obtained in ZnO/GaN nanorod coaxial quantum structures.

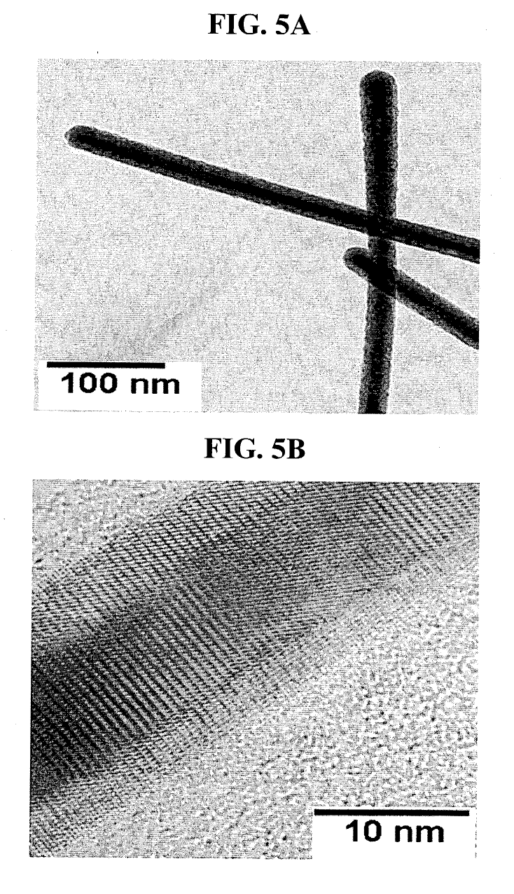

Referring to FIGS. 5A and 5B, the contrast difference between the center and the edge of the nanorod indicates that the nanorod structures composed of two different layers of core ZnO, and shell ZnMgO (FIG. 5A) and GaN (FIG. 5B). The diameter of the core ZnO was about 10 nm and the thickness of the shell layer of ZnMgO and GaN were about 10 nm and 5 nm, respectively. The interface between ZnO and GaN is atomically abrupt and clean, indicating ZnO based coaxial quantum structure was well fabricated.

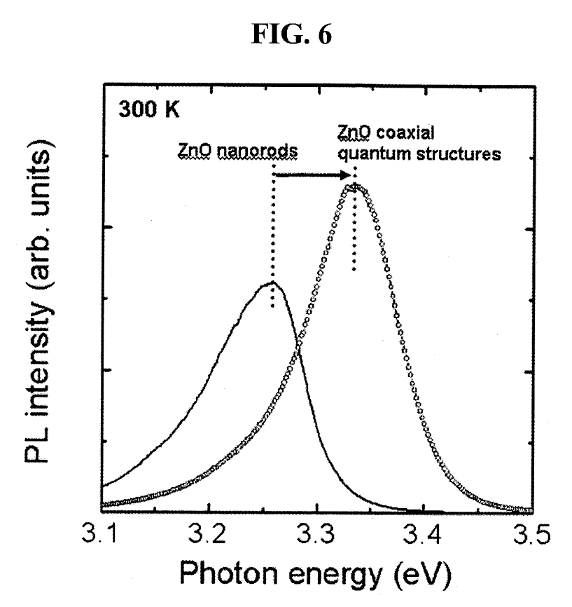

Referring to FIG. 6, quantum confinement effect was also observed in ZnO based nanorod with coaxial quantum structure of the present invention. While room temperature PL spectrum of ZnO nanorod exhibited the dominant free exciton peak at 3.27 eV corresponding to bulk ZnO, ZnO based nanorods with coaxial quantum structures exhibited the blue shift in excitonic emission peaks in the range of 10-80 meV depending on the core ZnO nanorod diameters. In addition, the luminescent intensities of ZnO based nanorods with coaxial quantum structures increased rapidly with increasing ZnMgO shell widths. Since the excitons generated in ZnMgO layers might be fall down to the ZnO cores, the enhanced exciton density as well as the enhanced confinement might increase the emission efficiency.

In addition to the ZnO/Zn₁₋ₓMgₓO (0<x<1) quantum structure, it is understood that various quantum well or coaxial quantum structures made of ZnO; and Zn₁₋ₓCoₓO, Zn₁₋ₓMnₓO, Zn₁₋ₓCdₓO (0<x<1), or an alloy thereof can be manufactured using the aforementioned method.

In addition to the ZnO/GaN quantum structure, it is understood that various quantum well or coaxial quantum structures made of GaN; and AlₓGa₁₋ₓN, InₓGa₁₋ₓN (0<x<1), or an alloy thereof can be manufactured using the aforementioned method.

As apparent from the above description, the present invention provides a ZnO based nanorod with a quantum well or a coaxial quantum structure. The actual and substantial advantages of ZnO based nanorods of the present invention are as follows.

Because of accelerated progress in information society, importance of developments of nanomaterials and nanodevices using the nanomaterials is increasing. Nanorods were manufactured using a metal catalyst in 1967. After then, various techniques using a metal catalyst were developed and used for manufacturing various nanorods. Based on these techniques, many attempts had been made to incorporate various structures into a single nanorod structure. However, development of nanorods having heterojunction structures was the only outcome. The present invention provides new nanorod with a quantum well or a coaxial quantum structure. Therefore, a complicated structure can be incorporated into a single nanorod. In particular, by incorporating a new structure into a single nanorod, a functional single nanorod can be obtained. Therefore, limitations of developments of nanodevices using a conventional bottom up process can be overcome. In particular, because ZnO semiconductors are oxide semiconductors having excellent electrical and optical properties, ZnO based nanorod with a quantum well or a coaxial quantum structure of the present invention can widely be used in various application fields such as high efficiency electronic nano-scale devices, optical nano-scale devices, and environmental nano-scale devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A zinc oxide based nanorod with a quantum well or a coaxial quantum structure.

2. The zinc oxide based nanorod according to claim 1, wherein the quantum well or the coaxial quantum structure is formed by alternately laminating two or more layers selected from the group consisting of a zinc oxide layer; and a Zn₁₋ₓMₓO layer, where M is Mg, Cd, Mn, Fe, Cu, or Co, and x is 0≦x≦1, and an alloy thereof, at one or more cycle.

3. The zinc oxide based nanorod according to claim 1, wherein the quantum well or the coaxial quantum structure is formed by alternately laminating two or more layers selected from the group consisting of a zinc oxide layer; and a metal oxide layer of one or more selected from the group consisting of MgO, Al₂O₃, TiO₂ and an alloy thereof, at one or more cycle.

4. The zinc oxide based nanorod according to claim 1, wherein the quantum well or the coaxial quantum structure is formed by alternately laminating two or more layers selected from the group consisting of a zinc oxide layer; and a semiconductor layer of one or more selected from the group consisting of GaN, AlN, InN, GaAs, InP, GaSb, SiC, ZnSe, CdS, ZnS and an alloy thereof, at one or more cycle.

5. The zinc oxide based nanorod according to any one of claims 1 to 4, which is manufactured by organic chemical vapor deposition in the absence of a metal catalyst.

6. A nano-scale device using the nanorod according to any one of claims 1 to 4.

7. The nano-scale device according to claim 6, wherein the nano-scale device is selected from the group consisting of electronic nano-scale devices, optical nano-scale devices, and environmental nano-scale devices.
